(19) United States
(12) Patent Application Publication
(10) Pub. No.: US 2016/0087002 A1
(43) Pub. Date: Mar. 24, 2016

(54) SOLID STATE IMAGING DEVICE AND METHOD OF FABRICATING THE SAME

(71) Applicant: Kabushiki Kaisha Toshiba, Minato-ku (JP)

(72) Inventor: Kokichi HASHIMOTO, Oita (JP)

(73) Assignee: Kabushiki Kaisha Toshiba, Minato-ku (JP)

(21) Appl. No.: 14/628,775

(22) Filed: Feb. 23, 2015

(30) Foreign Application Priority Data
Sep. 24, 2014 (JP) 2014-194493

(51) Int. Cl. H01L 27/146

(52) U.S. Cl. CPC H01L 27/14685; H01L 27/14636; H01L 27/14621; H01L 27/1462; H01L 27/14627; H01L 27/14612; H01L 27/14643

(57) ABSTRACT

According to one embodiment, a semiconductor substrate has a first region in which a photoelectric conversion device is provided, a second region which is provided around the first region, and in which a device is provided, and a third region which is provided between the first region and the second region, and in which the photoelectric conversion device is provided. A first interlayer insulating film is provided on the first region and the third region. A second interlayer insulating film is provided on the second region, and is thicker than the first interlayer insulating film. A resin material is provided on the first interlayer insulating film of the first region, and provided so as to cover a groove of a surface of the first interlayer insulating film of the third region.

### CROSS REFERENCE TO RELATED APPLICATION

This application is based upon and claims the benefit of priority from the prior Japanese Patent Application No. 2014-194493, filed on Sep. 24, 2014, the entire contents of which are incorporated herein by reference.

### FIELD

Embodiments described herein relate to a solid state imaging device and a method of fabricating the solid state imaging device.

### BACKGROUND

A solid state imaging device is provided with a semiconductor substrate, and the semiconductor substrate has a pixel region and a peripheral region. An interlayer insulating film and a wiring in the interlayer insulating film are provided on the semiconductor substrate. A plurality of photoelectric conversion devices each of which converts incident light into an electric signal are provided in the pixel region. The photoelectric conversion device receives a specific wavelength of incident light which has passed through a microlens and a color filter provided above the photoelectric conversion device, as color information. Since the number of wirings provided in the interlayer insulating film of the pixel region is different from the number of wirings in the interlayer insulating film of the peripheral region, a step between the interlayer insulating films is generated at a boundary between the pixel region and the peripheral region.

The color filter is formed using a spin coating method in which coloring resin material is dripped on the interlayer insulating film in the pixel region, and the material is spread by rotating the semiconductor substrate. For this reason, a liquid pool is generated at the step portion. As a result, the thickness of the color filter becomes non-uniform between the central portion of the pixel region and the peripheral region side. Since the thickness of the color filter becomes non-uniform, there may be a case in which the color information which the photoelectric conversion device located at the central portion of the pixel region acquires differs from the color information which the photoelectric conversion device located in the pixel region at the peripheral region side. For this reason, in a conventional solid state imaging device, a region in which the thickness of the color filter in the pixel region is uniform is determined as an effective pixel region capable of acquiring the color information. A prohibited pixel region is provided in the pixel region where a liquid pool may be generated, and the color information has not been acquired therein.

### BRIEF DESCRIPTION OF THE DRAWINGS

FIG. 1 is a schematic plan view showing a configuration of a solid state imaging device according to a first embodiment;

FIG. 2 is a schematic circuit diagram showing a circuit configuration of a pixel region and the vicinity of the pixel region of the solid state imaging device according to the first embodiment;

FIG. 3 is a sectional view showing a structure of the solid state imaging device along a line Ia-Ia of FIG. 1;

FIG. 4 is a sectional view showing a structure of a solid state imaging device of a comparative example;

FIG. 5 is a sectional view showing a fabrication process of the solid state imaging device according to the first embodiment;

FIG. 6 is a sectional view showing a fabrication process of the solid state imaging device according to the first embodiment;

FIG. 7 is a sectional view showing a fabrication process of the solid state imaging device according to the first embodiment;

FIG. 8 is a sectional view showing a fabrication process of the solid state imaging device according to the first embodiment;

FIG. 9 is a sectional view showing a fabrication process of the solid state imaging device according to the first embodiment;

FIG. 10 is a sectional view showing a fabrication process of the solid state imaging device according to the first embodiment;

FIG. 11 is a sectional view showing a fabrication process of the solid state imaging device according to the first embodiment;

FIG. 12 is a sectional view showing a fabrication process of the solid state imaging device according to the first embodiment;

FIG. 13 is a sectional view showing a fabrication process of the solid state imaging device according to the first embodiment; and

FIG. 14 is a sectional view showing a configuration of a solid state imaging device according to a second embodiment.

### DETAILED DESCRIPTION

According to one embodiment, a solid state imaging device includes a semiconductor substrate, a first interlayer insulating film, a second interlayer insulating film, and a resin material. The semiconductor substrate has a first region in which a photoelectric conversion device is provided, a second region which is provided around the first region, and in which a device is provided, and a third region which is provided between the first region and the second region, and in which the photoelectric conversion device is provided. The first interlayer insulating film is provided on the first region and the third region. The second interlayer insulating film is provided on the second region, and is thicker than the first interlayer insulating film. The resin material is provided on the first interlayer insulating film of the first region, and provided so as to cover a groove of a surface of the first interlayer insulating film of the third region.

Hereinafter, further embodiments will be described with reference to the drawings. In the drawings, the same symbols show the same or similar portions.

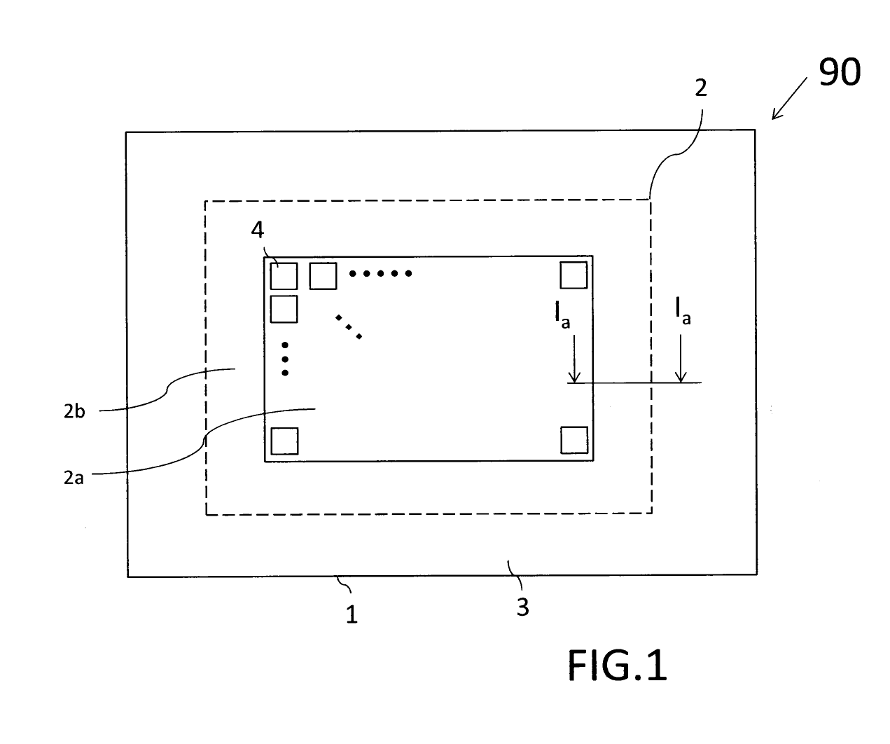

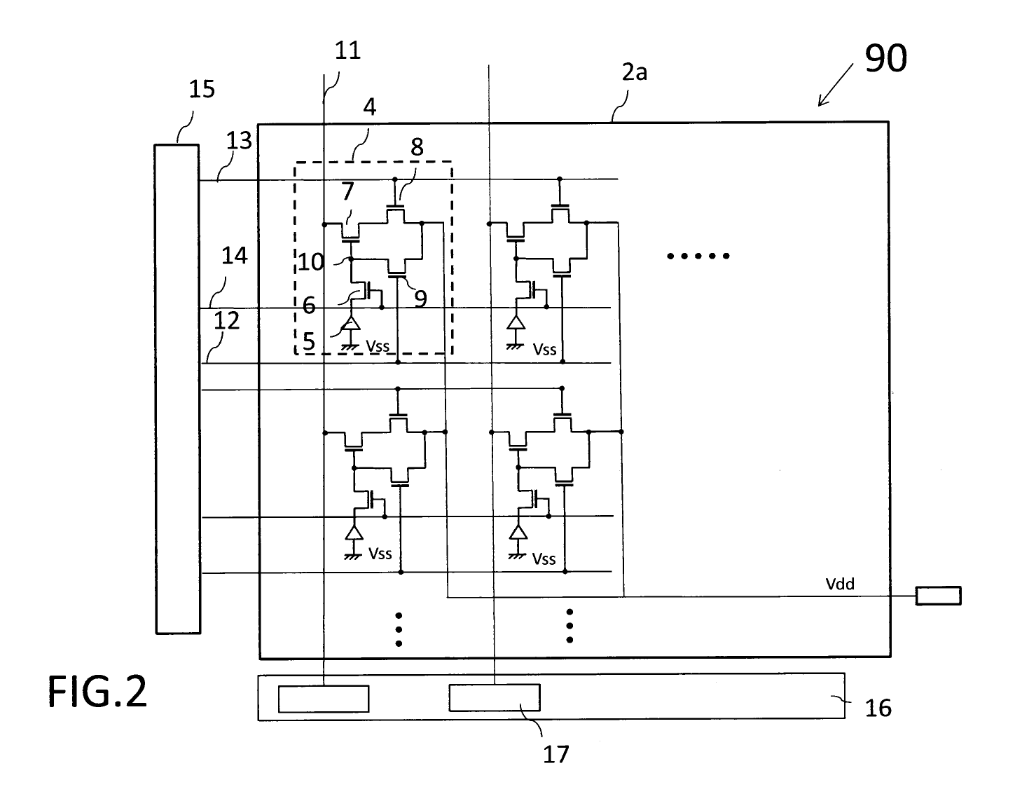

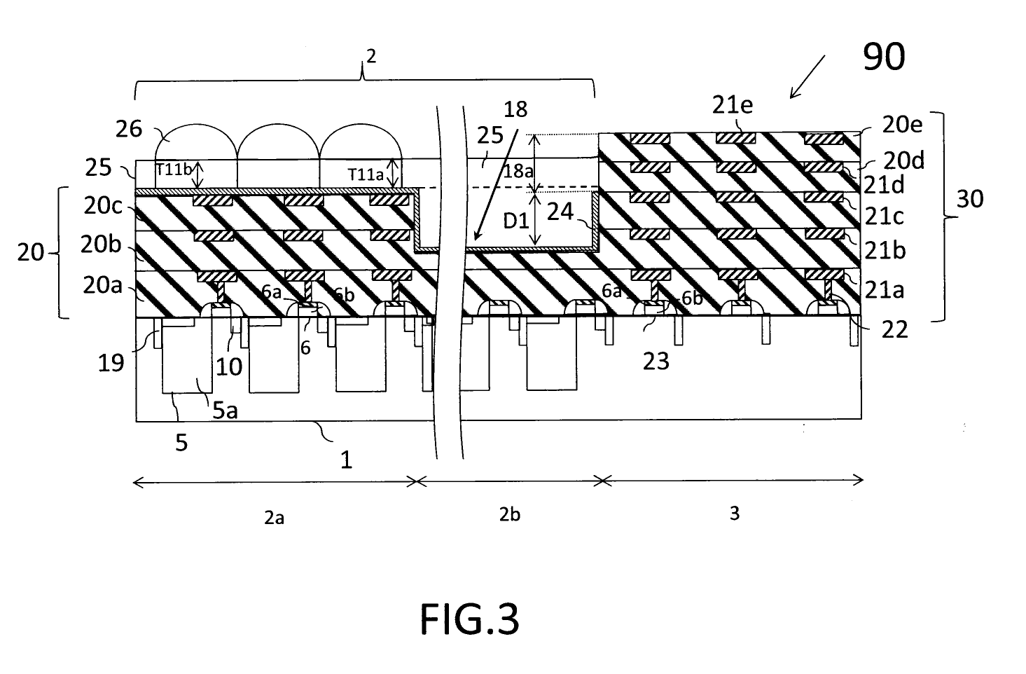

A solid state imaging device and a method of fabricating the solid state imaging device according to a first embodiment will be described with reference to the drawings. FIG. 1 is a schematic plan view showing a configuration of a solid state imaging device. FIG. 2 is a schematic circuit diagram showing a circuit configuration of a pixel region and a vicinity of the pixel region of the solid state imaging device. FIG. 3 is a sectional view showing a structure of the solid state imaging device along a line Ia-Ia of FIG. 1.

In the embodiment, a semiconductor substrate of the solid state imaging device includes a first region in which a photoelectric conversion device is provided, a second region which is provided around the first region, and in which a device is provided, and a third region which is provided between the first region and the second region, and in which a photoelectric conversion device is provided. A groove is formed in a surface of an interlayer insulating film on the semiconductor substrate of the third region, to make a film thickness of a color filter on the first region uniform, and to increase an effective pixel region.

As shown in FIG. 1, a solid state imaging device 90 includes a semiconductor substrate 1. The semiconductor substrate 1 includes a pixel region 2 and a peripheral region 3 (the second region). The pixel region 2 has an effective pixel region 2a (the first region) and a prohibited pixel region 2b (the third region). The prohibited pixel region 2b is provided between the effective pixel region 2a and the peripheral region 3. The effective pixel region 2a has a rectangle shape from the surface side. Each of the peripheral region 3 and the prohibited pixel region 2b has a frame shape from the surface side.

The effective pixel region 2a and the prohibited pixel region 2b have a plurality of pixels 4 which are arrayed in a matrix. Since the prohibited pixel region 2b is not provided with wirings, the pixel 4 does not operate in the prohibited pixel region 2b. Details of the prohibited pixel region 2b will be described later.

As a solid state image device, there are a surface irradiation type solid state imaging device in which light enters from a surface side of a semiconductor substrate, and a back surface irradiation type solid state imaging device in which light enters from a back surface side of a semiconductor substrate. The solid state imaging device 90 of the embodiment is a surface irradiation type solid state imaging device.

As shown in FIG. 2, the solid state imaging device 90 is provided with the effective pixel region 2a, a vertical drive circuit 15, and an AD conversion circuit 16. The vertical drive circuit 15 and the AD conversion circuit 16 are provided in the peripheral region 3.

In the effective pixel region 2a, a plurality of the pixels 4 are provided. The pixel 4 is provided with a photo diode 5 (a photoelectric conversion device), a transfer transistor 6, an amplifier transistor 7, a selection transistor 8, and a reset transistor 9. The transfer transistor 6, the amplifier transistor 7, the selection transistor 8, and the reset transistor 9 are each composed of an N-channel MOS transistor.

Though not shown in FIG. 2, in the prohibited pixel region 2b, the photo diode 5, the transfer transistor 6, the amplifier transistor 7, the selection transistor 8, and the reset transistor 9 are provided. In the prohibited pixel region 2b, wirings composing a vertical signal line 11, a reset signal line 12, a selection signal line 13, a read signal line 14, a power source line to transmit a power source voltage Vdd are not provided. For this reason, the pixel 4 does not operate in the prohibited pixel region 2b.

The photo diode 5 is a photoelectric conversion device. The photo diode 5 has an anode connected to a ground potential Vss, and a cathode connected to a source of the transfer transistor 6. The photo diode 5 accumulates charge which has been generated in accordance with a amount of light which has passed through a color filter (not shown).

The transfer transistor 6 has a drain connected to a floating diffusion (hereinafter, referred to as an FD) 10, and a gate connected to the read signal line 14.

In the transfer transistor 6, when a voltage of a “High” level transmitted via the read signal line 14 is applied to the gate, a channel layer is formed on a surface of the semiconductor substrate immediately below stacked gate electrode and gate insulating film. The charge which has been accumulated in the photo diode 5 is read to the FD 10 via the channel layer. As a result of this read, the FD 10 is set to a read potential.

The amplifier transistor 7 has a source connected to the vertical signal line 11, and a gate connected to the FD 10.

When a potential of the FD 10 is applied to the gate of the amplifier transistor 7, the amplifier transistor 7 amplifies the applied voltage and outputs the amplified voltage to the vertical signal line 11.

The selection transistor 8 has a source connected to the drain of the amplifier transistor 7, a gate connected to the selection signal line 13, and a drain to which the power source voltage Vdd is applied.

When a voltage of a “High” level transmitted via the selection signal line 13 is applied to the gate of the selection transistor 8, the selection transistor 8 is turned on, amplifies the applied voltage and outputs the amplified voltage to the drain of the amplifier transistor 7. The selection transistor 8 selects the pixel 4 which performs reading of a signal.

The reset transistor 9 has a source connected to the FD 10, a gate connected to the reset signal line 12, a drain to which the power source voltage Vdd is applied.

When a voltage of a “High” level transmitted via the reset signal line 12 is applied to the gate of the reset transistor 9, the reset transistor 9 is turned on, to set the FD 10 to a reset potential.

The vertical drive circuit 15 controls and selects the pixels 4 in the effective pixel region 2a in a row unit.

The vertical drive circuit 15 is connected to the reset signal line 12, the selection signal line 13, and the read signal line 14. The vertical drive circuit 15 controls the reset transistor 9 via the reset signal line 12. The vertical drive circuit 15 controls the selection transistor 8 via the selection signal lien 13. The vertical drive circuit 15 controls the transfer transistor 6 via the read signal line 14.

The AD conversion circuit 16 is connected to the vertical signal line 11 corresponding to the respective pixels. The AD conversion circuit 16 analog-to-digital converts the voltage outputted from the amplifier transistor 7. The AD conversion circuit 16 has a plurality of CDSs (Correlated Double Sampling) 17.

The CDS 17 performs CDS processing to obtain the difference between the read voltage and the reset voltage, to remove the noise contained in the pixel 4.

Hereinafter, a reading operation from the pixel 4 of the effective pixel region 2a will be described.

When the voltage of the “High” level outputted from the vertical drive circuit 15 is applied to the gate of the selection transistor 8, the pixel 4 to be operated is determined.

When the voltage of the “High” level outputted from the vertical drive circuit 15 is applied to the gate of the reset transistor 9, the FD 10 becomes the reset voltage. When the reset voltage is applied to the gate of the amplifier transistor 7, the reset voltage is amplified by the amplifier transistor 7, and the amplified reset voltage is transmitted to the vertical signal line 11 as an output signal from the pixel 4. The transmitted reset voltage is inputted to the AD conversion circuit 16.

When the voltage of the “High” level outputted from the vertical drive circuit 15 is applied to the gate of the transfer transistor 6, a channel layer is formed on the surface of the semiconductor substrate 1 immediately below the stacked gate electrode and gate insulating film. The charge which has been accumulated in the photo diode 5 is read to the FD 10 via the channel layer. A potential of the FD 10 becomes a value corresponding to the number of read charges. When the read voltage is applied to the gate of the amplifier transistor 7, the read voltage is amplified by the amplifier transistor 7, and the read voltage is outputted as an output signal from the pixel 4. The read voltage is inputted to the AD conversion circuit 16.

The reset voltage and the read voltage are sequentially converted from an analog value to a digital value by the AD conversion circuit 16. In addition to the AD conversion of the voltage values, CDS processing is performed to the reset voltage and the read voltage. A difference value between the reset voltage and the read voltage is outputted to an image processing circuit (not shown) as pixel data D sig.

As described above, the read operation to the effective pixel region 2a is repeated, and thereby a prescribed image is formed.

As shown in FIG. 3, the solid state imaging device 90 has the semiconductor substrate 1, the transfer transistor 6, interlayer insulating films 20a to 20e, wirings 21a to 21e, a contact 22, a device 23, an antireflection film 24, a color filter 25 (a resin material), and a microlens 26. In addition, in FIG. 3, the amplifier transistor 7, the selection transistor 8, the reset transistor 9, the vertical drive circuit 15, and the AD conversion circuit 16 are not shown, for simplifying explanations.

The solid state imaging device 90 is a surface irradiation type CMOS sensor in which light enters the photodiode 5 of the semiconductor substrate 1 through the microlens 26, the color filter 25, and the interlayer insulating films 20a to 20c.

The semiconductor substrate 1 is a P-type silicon substrate, for example. The semiconductor substrate 1 includes the photo diode 5, the FD 10, an element isolation layer 19. The photo diodes 5 are provided in the surfaces of the effective pixel region 2a and the prohibited pixel region 2b of the semiconductor substrate 1. The photo diode 5 has an N-type impurity layer 5a with an impurity concentration higher than that of the semiconductor substrate 1.

The element isolation layers 19 are formed in the surfaces of the effective pixel region 2a, the prohibited pixel region 2b, and the peripheral region 3 of the semiconductor substrate 1. In the effective pixel region 2a and the prohibited pixel region 2b, the element isolation layer 19 is in contact with one side surface of the photo diode 5. The element isolation layer 19 has a depth smaller than that of the photo diode 5.

The FDs 10 are formed in the surfaces of the effective pixel region 2a and the prohibited pixel region 2b of the semiconductor substrate 1. The FD 10 is an N-type impurity layer. The FD 10 is in contact with the element isolation layer 19, and faces one side surface of the photo diode 5 via the element isolation layer 19. The FD 10 has a depth smaller than that of the element isolation layer 19.

The transfer transistors 6 are respectively provided at a boundary region of the interlayer insulating film 20a and the effective pixel region 2a of the semiconductor substrate 1, and at a boundary region of the interlayer insulating film 20a and the prohibited pixel region 2b. The transfer transistor 6 has a gate electrode 6a and a gate insulating film 6b which are stacked and formed on the semiconductor substrate 1. The transfer transistor 6 has a source, a drain, and a channel layer which are provided in the surface of the semiconductor substrate 1. In the transfer transistor 6, the source is the N-type impurity layer 5a, the drain is the FD 10, and the surface of the semiconductor substrate 1 between the N-type impurity layer 5a and the FD 10 forms the channel layer.

When the transfer transistor 6 reads the charge which has been accumulated in the photo diode 5, when a voltage is applied to the gate electrode 6a of the transfer transistor 6, the channel layer is formed in the surface of the semiconductor substrate 1 via the gate insulating film 6b. As a result, the charge which has been accumulated in the photo diode 5 is transferred to the FD 10 via the channel.

A MOS transistor 23 (device) is provided at a boundary region between the peripheral region 3 of the semiconductor substrate 1 and the interlayer insulating film 20a. The MOS transistor 23 has the stacked gate electrode 6a and the gate insulating film 6b provided on the semiconductor substrate 1. The MOS transistor 23 has a source, a drain, and a channel layer which are not shown and are provided in the surface of the semiconductor substrate 1. In the periphery region 3 of the semiconductor substrate 1, a resistance element and a capacitance element (not shown) are provided.

The effective pixel region 2a is a region in which the light which has passed through the color filter 25 is received by the photo diode 5, and color information can be obtained. The prohibited pixel region 2b is a region in which light is not received by the photo diode 5, but which is provided for adjusting the thickness of the color filter 25.

The interlayer insulating film 20a of a first layer is provided on the semiconductor substrate 1. A plurality of the wirings 21a are provided in the interlayer insulating film 20a of the effective pixel region 2a and the peripheral region 3. The wiring 21a is not provided in the interlayer insulating film 20a of the prohibited pixel region 2b.

The wirings 21a provided in the interlayer insulating film 20a are connected to the gate electrode 6a of the transfer transistor 6, the FD 10 and the gate electrode (not shown) of the amplifier transistor 7 via the contact 22, in the vertical direction of the semiconductor substrate 1.

The interlayer insulating film 20b of a second layer is provided on the interlayer insulating film 20a. The wiring 21b is provided in the interlayer insulating film 20b of the effective pixel region 2a and the peripheral region 3. The wiring 21b is electrically connected to the wiring 21a via a via hole (not shown), in the vertical direction of the semiconductor substrate 1.

The interlayer insulating film 20c of a third layer is provided on the interlayer insulating film 20b. The wiring 21c is provided in the interlayer insulating films 20c of the effective pixel region 2a and the peripheral region 3. The wiring 21c is electrically connected to the wiring 21b via a via hole (not shown), in the vertical direction of the semiconductor substrate 1.

In the peripheral region 3, the interlayer insulating film 20d of a fourth layer is provided on the interlayer insulating film 20c. The wiring 21d is provided in the interlayer insulating films 20d of the peripheral region 3. The wiring 21d is electrically connected to the wiring 21c via a via hole (not shown), in the vertical direction of the semiconductor substrate 1.

In the peripheral region 3, the interlayer insulating film 20e of a fifth layer is provided on the interlayer insulating film 20d. The wiring 21e is provided in the interlayer insulating films 20e of the peripheral region 3. The wiring 21e is electrically connected to the wiring 21d via a via hole (not shown), in the vertical direction of the semiconductor substrate 1.

The power source voltage Vdd is supplied from outside via the wirings 21a to 21e, so as to make the circuits and devices to be operated, but the description thereof will be omitted here for the sake of simplicity.

An interlayer insulating film 20 (a first interlayer insulating film) composed of the interlayer insulating films 20a to 20c is provided, in the effective pixel region 2a and the prohibited pixel region 2b.

An interlayer insulating film 30 (a second interlayer insulating film) composed of the interlayer insulating films 20a to 20e in the peripheral region 3.

As a result, a step 18a is generated at the boundary between the pixel region 2 and the peripheral region 3. In the embodiment, in order to suppress the variation of the film thickness of the color filter 25 in the pixel region 2 caused by the step to a large extent, a groove 18 is formed in the surface of the interlayer insulating film 20 of the prohibited pixel region 2b.

In the embodiment, the number of the layers of the interlayer insulating films of the effective pixel region 2a and the prohibited pixel region 2b is three, but the number is not necessarily limited to this.

The number of the layers of the interlayer insulating films of the peripheral region 3 is five, but the number is not necessarily limited to this. The number of the layers of the interlayer insulating films of the peripheral region 3 is formed larger than the number of layers of the interlayer insulating films of the effective pixel region 2a.

As the interlayer insulating films 20a to 20e, a silicon oxide film of TEOS (Tetra Ethylortho Silicate) or the like, or a Low-k insulating film is used.

In the prohibited pixel region 2b, the groove 18 is formed in the surface of the interlayer insulating film 20 (the first interlayer insulating film). The groove 18 has one side surface in contact with the effective pixel region 2a, and the other side surface in contact with the peripheral region 3. The groove 18 has a depth D1, and penetrates through the interlayer insulating film 20c, and reaches the interlayer insulating film 20b. The groove 18 is provided so as to surround the effective pixel region 2a.

The depth D1 of the groove 18 is provided in the range from 1 μm to 1.5 μm, for example. The width of the groove 18 is about the width of four pixels, for example.

The antireflection film 24 is provided on the interlayer insulating film 20c of the effective pixel region 2a, and on the side surfaces and the bottom surface of the groove 18.

The color filter 25 is provided on the antireflection film 24 of the effective pixel region 2a, and on the antireflection film 24 of the groove 18, so as to cover the groove 18.

The groove 18 is provided in the prohibited pixel region 2b.

As a result, it is possible to reduce a film thickness T11a of the color filter 25 in the effective pixel region 2a in contact with the prohibited pixel region 2b, and a film thickness T11b of the color filter 25 at the central portion of the effective pixel region 2a.

The microlens 26 is provided on the color filter 25 of the effective pixel region 2a. Since the film thickness of the color filter 25 in the effective pixel region 2a is uniform, the microlens 26 in the effective pixel region 2a in contact with the prohibited pixel region 2b, and the microlens at the central portion of the effective pixel region 2a can be formed in the same shape.

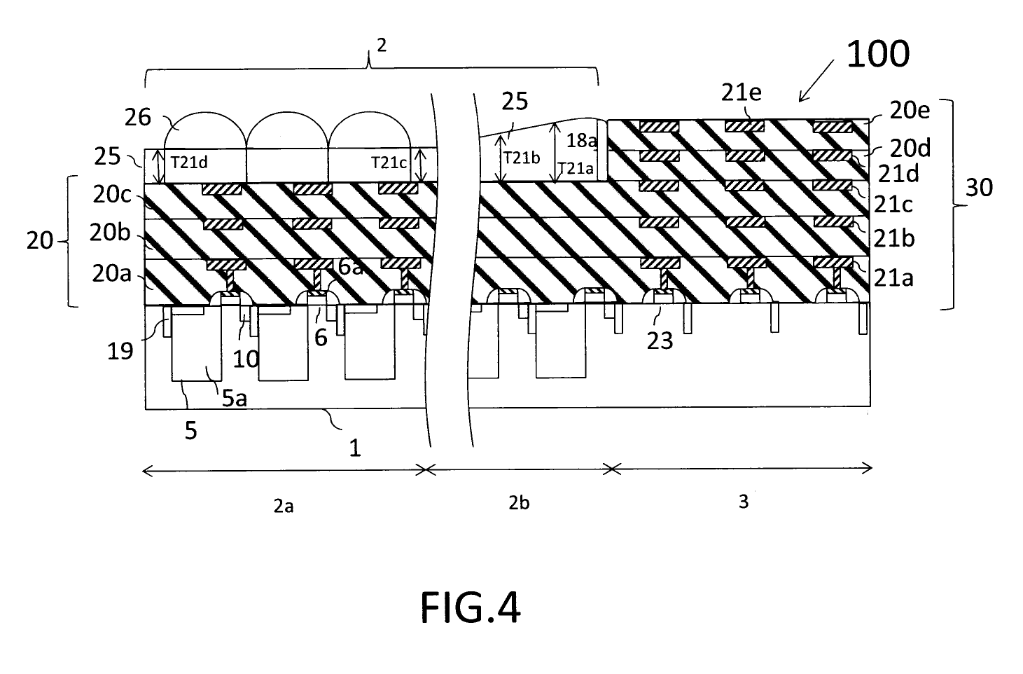

Next, a solid state imaging device of a comparative example will be described with reference to FIG. 4. FIG. 4 is a sectional view showing a structure of a solid state imaging device of a comparative example.

As shown in FIG. 4, in a solid state imaging device 100 of a comparative example, the groove 18 and the wirings 21a to 21c are not provided in the prohibited pixel region 2b. The antireflection film 24 is not provided in the effective pixel region 2a and the prohibited pixel region 2b. Since the other portions are the same as the solid state imaging device 90 of the embodiment, only different portions will be described.

In the solid state imaging device 100 of the comparative example, the step 18a is generated between the interlayer insulating film 20c that is the uppermost layer of the pixel region 2, and the interlayer insulating film 20e that is the uppermost layer of the peripheral region 3. The step 18a is in the range from 1.5 μm to 2.0 μm, for example.

The color filter 25 is composed of a Bayer array in which a plurality of sets are regularly arrayed, each of which is composed of one pixel for red, two pixels for green, one pixel for blue, in four pixels of 2×2. The color filter 25 of each color is provided so as to correspond to the pixel 4 containing the photo diode 5.

The thickness of the color filter 25 differs depending on the coloring resin material composing the color filter 25, but a constant thickness is required in order to hold desired color characteristic. The thickness is in the range from 1.0 μm to 1.3 μm, for example

Since the groove 18 is not provided in the prohibited pixel region 2b, in the solid state imaging device 100 of the comparative example, the film thickness of the color filter 25 provided on the interlayer insulating film 20c differs depending on a place (the effective pixel region 2a, the prohibited pixel region 2b). The reason is because when the color filter 25 is formed by applying liquid coloring resin material on the solid state imaging device 100 of the comparative example, and rotating the semiconductor substrate 1, a liquid pool is generated in the prohibited pixel region 2b. For this reason, the nearer to the peripheral region 3 side from the effective pixel region 2a, the more the film thickness of the color filter 25 increases.

That is, assuming that a film thickness of the color filter 25 in the prohibited pixel region 2b in contact with the peripheral region 3 is T21a, a film thickness of the color filter 25 in the central region of the prohibited pixel region 2b is T21b, a film thickness of the color filter 25 in the effective pixel region 2a in contact with the prohibited pixel region 2b is T21c, and a film thickness of the color filter 25 in the central region of the effective pixel region 2a is T21d, these values are expressed as follows.

T21a>T21b>T21c>T21d Expression (1)

In the solid state imaging device 100 of the comparative example, since the film thickness of the color filter 25 in the effective pixel region 2a becomes non-uniform, the shape of the microlens 26 becomes non-uniform.

In the solid state imaging device 90 of the embodiment, the groove 18 is provided in the surface of the interlayer insulating film 20 of the prohibited pixel region 2b. When the color filter 25 is formed by applying and rotating the liquid coloring resin material, the groove 18 is filled with a liquid pool of the coloring resin material. As a result, the liquid pool to be generated at the step 18a can be reduced to a large extent.

It is possible to increase the region where the thickness of the color filter 25 is uniform, by reducing the liquid pool. The region where the thickness of the color filter 25 is uniform is increased, to thereby increase the range where the microlens 26 can be formed. As a result, it is possible to considerably reduce the prohibited pixel region 2b in which light is not received by the photo diode 5 and which is used for the adjustment of the thickness of the color filter 25, and the effective pixel region 2a can be increased. It is possible to enlarge the range where the light which has passed through the color filter 25 can be acquired by the photo diode 5 without color information unevenness.

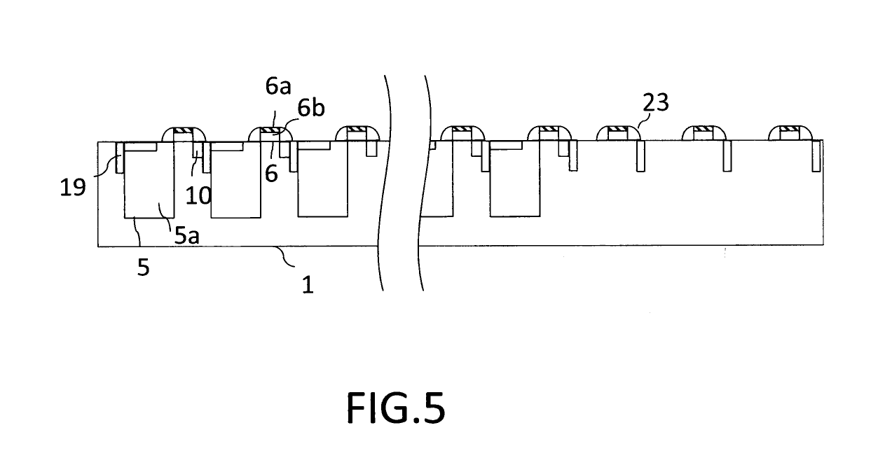

Next, a method of fabricating a solid state imaging device of the embodiment will be described with reference to the drawings. FIG. 5 to FIG. 13 are sectional views each showing a fabricating process of the solid state imaging device.

As shown in FIG. 5, the element isolation layer 19 is formed in the semiconductor substrate 1. After the element isolation layer 19 is formed, the gate insulating film 6b is formed on the surface of the semiconductor substrate 1 by using a thermal oxidation method, for example. A polycrystalline silicon film doped with impurities, for example, is formed on the gate insulating film 6b.

After the polycrystalline silicon film is formed, the gate insulating film 6b and the polycrystalline silicon film are etched by using an RIE (Reactive Ion Etching) method, using a resist film (not shown) formed by using a photolithography method as a mask. As a result, in the pixel region 2, the gate electrode 6a and the gate insulating film 6b of the transfer transistor 6 are syacked and formed on the semiconductor substrate 1. In the peripheral region 3, the gate electrode 6a and the gate insulating film 6b of the MOS transistor 23 are stacked and formed on the semiconductor substrate 1.

A first mask material (not shown) is formed on the semiconductor substrate 1. N-type impurity ions are implanted into a photo diode forming region, using the first mask material as a mask, by using an ion implantation method or the like, for example.

After the first mask is removed, a second mask material (not shown) is formed on the semiconductor substrate 1. N-type impurity ions are implanted into a FD 10 forming region, using the second mask material as a mask, by using an ion implantation method or the like, for example.

After the ion implantation, the second mask is removed. A side wall insulating film is formed on the side surfaces of the gate electrode 6a and the gate insulating film 6b.

After the side wall insulating film is formed, N-type impurity ions are implanted into the surface of the N-type impurity layer 5a, using the side wall insulating film as a mask, by using an ion implantation method or the like, for example. Heat treatment is performed, to activate the ion implantation layer and to form the N-type impurity layer 5a, the FD 10 and so on.

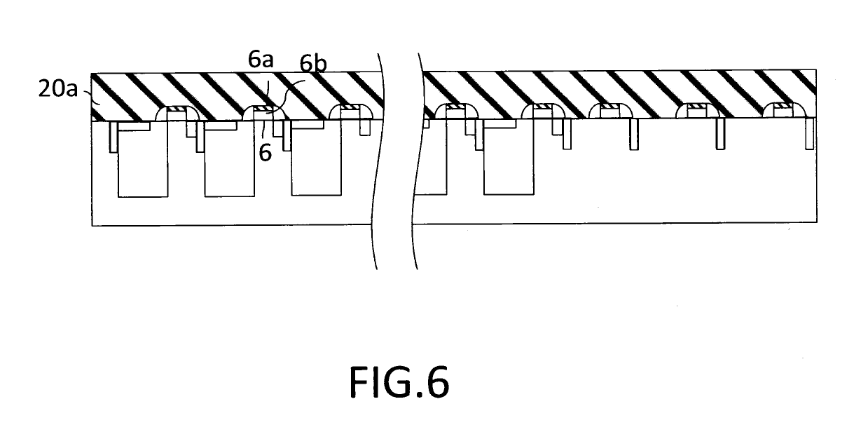

As shown in FIG. 6, the interlayer insulating film 20a is formed on the semiconductor substrate 1. The interlayer insulating film 20a is a silicon oxide film (SiO₂), for example. The silicon oxide film is formed by reacting mixed gas composed of gas containing silicon atoms such as monosilane (SiH₄), and oxygen gas, by adding heat energy. As a method to add the heat energy, a CVD (Chemical Vapor Deposition) method is used. In addition, the silicon oxide film may be formed using TEOS (Tetraethoxysilane) as raw material.

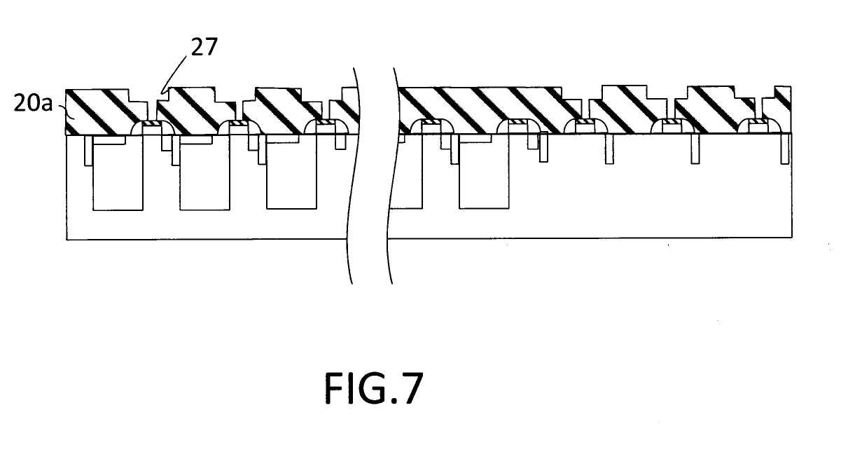

As shown in FIG. 7, a groove 27 for wiring having a T-type shape, for example, is formed in the surface of the interlayer insulating film 20a.

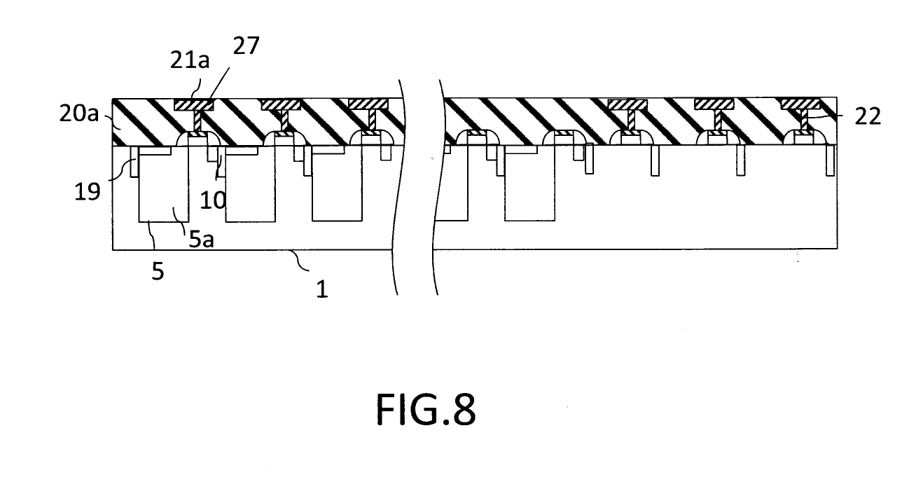

As shown in FIG. 8, conductive material is buried in the groove 27 for wiring, and thereby the wiring 21a is formed. The wiring 21a is formed by using a damascene method or a dual damascene method, for example. The groove 27 for wiring is formed by using a photolithography method and an RIE method, in accordance with the layout of the wirings. When the wiring 21a is formed by using the damascene method or the dual damascene method, it is preferable to use copper (Cu) as the wiring material, for example. The wiring material may be aluminium (Al). When the wiring material is aluminium, aluminium is formed on the interlayer insulating film 20a, and is fabricated in a prescribed shape, by using a photolithography method and an RIE method. As a result, the wiring 21a is formed in the interlayer insulating film 20a.

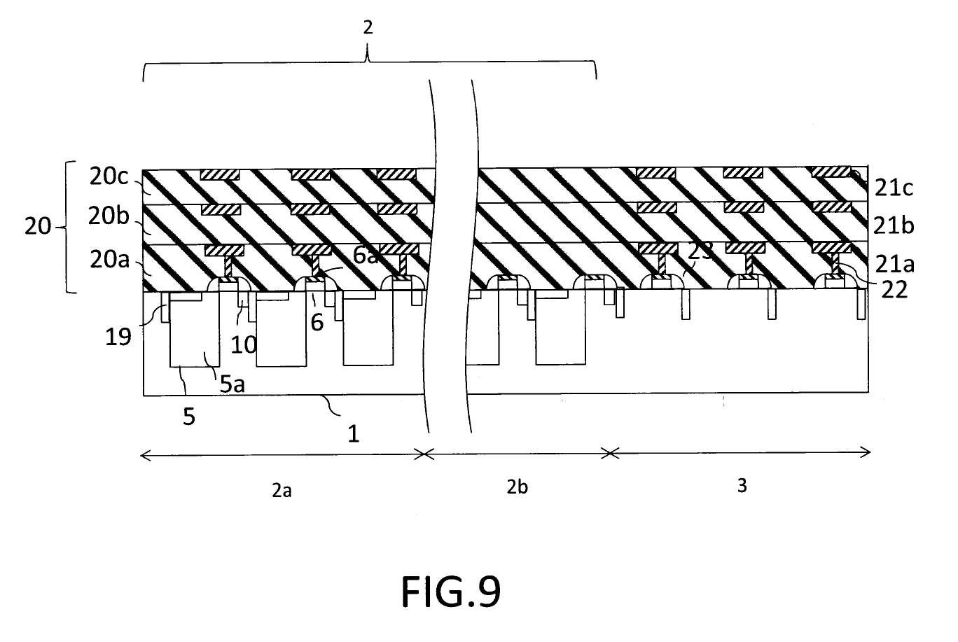

As shown in FIG. 9, the interlayer insulating film 20b and the interlayer insulating film 20c are formed by repeating the above-described processes. A flattening processing is performed to the interlayer insulating film 20c, by using a CMP (Chemical Mechanical Polishing) method. As a result, the interlayer insulating film 20 as the first interlayer insulating film is formed on the pixel region 2 of the semiconductor substrate 1.

The effective pixel region 2a formed with the wiring 21 and the prohibited pixel region 2b not formed with a wiring are formed on the pixel region 2 of the semiconductor substrate 1.

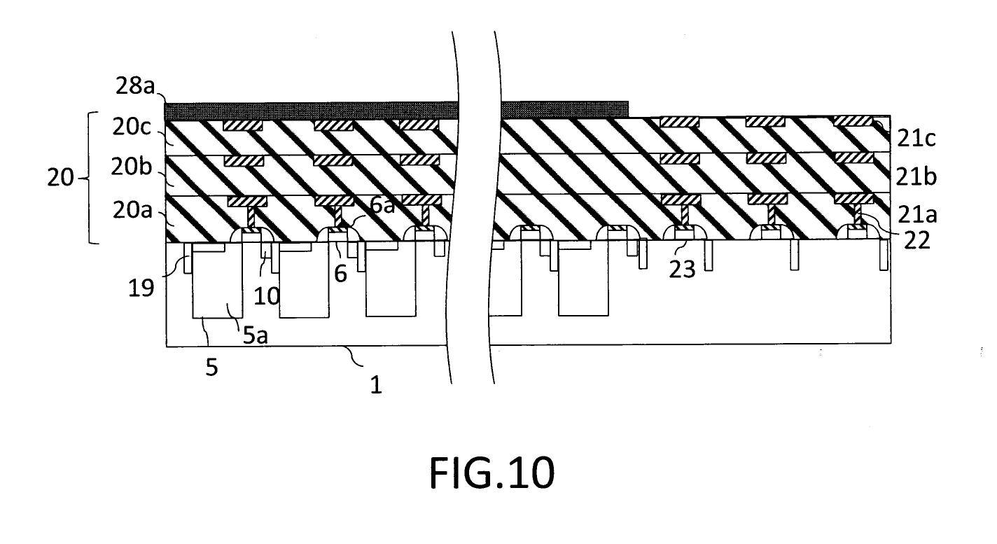

As shown in FIG. 10, a mask material 28a is formed on the interlayer insulting film 20c of the pixel region 2.

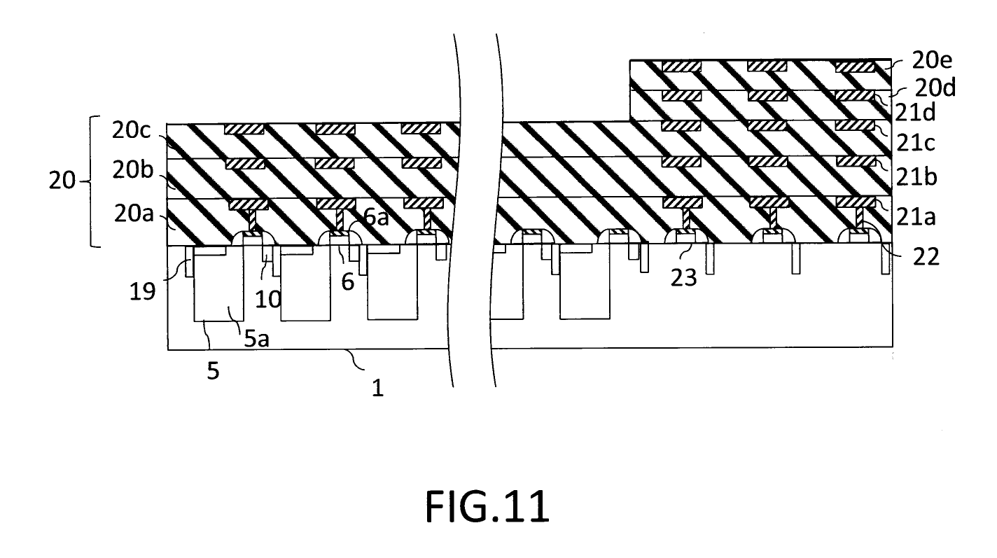

As shown in FIG. 11, the interlayer insulating film 20d is formed on the interlayer insulating film 20c of the peripheral region 3, by using the mask material 28a as a mask. The wiring 21d is formed at the surface of the interlayer insulating film 20d, by using the damascene method or the dual damascene method.

The interlayer insulating film 20e is formed on the interlayer insulating film 20d of the peripheral region 3, by using the mask material 28a as a mask. The wiring 21e is formed at the surface of the interlayer insulating film 20e, by using the damascene method or the dual damascene method.

A flattening processing is performed to the interlayer insulating film 20e of the peripheral region 3, by using the CMP (Chemical Mechanical Polishing) method. The mask material 28a is removed.

The interlayer insulating film 20 (the first interlayer insulating film) composed of the interlayer insulating films 20a to 20c is provided in the pixel region 2. The interlayer insulating film 30 (the second interlayer insulating film) composed of the interlayer insulating films 20a to 20e is provided in the peripheral region 3.

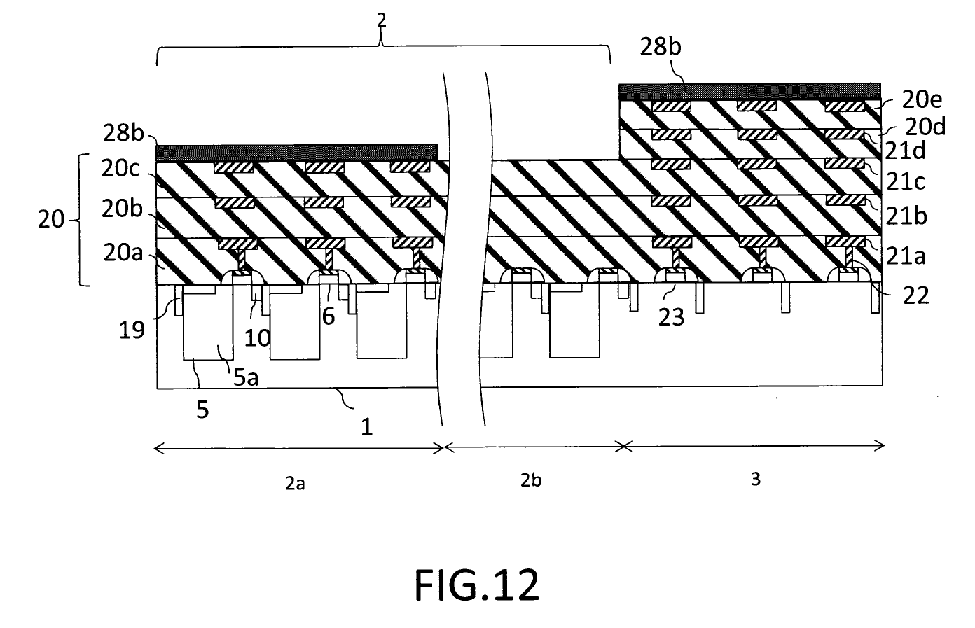

As shown in FIG. 12, mask materials 28b are respectively formed on the interlayer insulating film 20c of the effective pixel region 2a and on the interlayer insulating film 20e of the peripheral region 3.

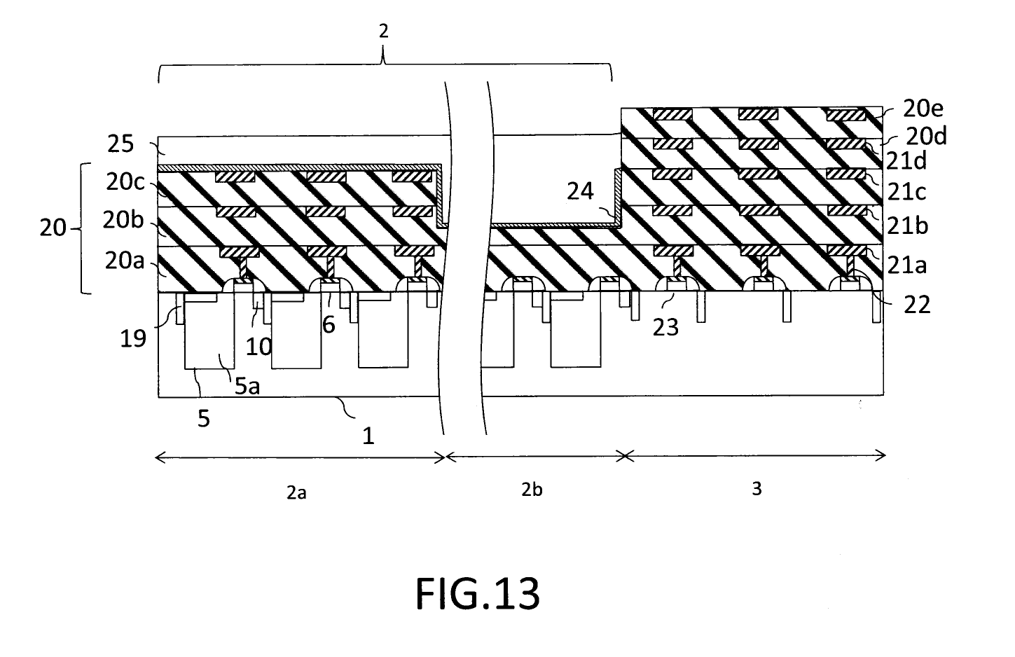

As shown in FIG. 13, the groove 18 is formed in the surface of the interlayer insulating film 20 of the prohibited pixel region 2b, by using the mask materials 28b as a mask, and by using an RIE method, for example. The groove 18 has one side surface in contact with the effective pixel region 2a, and the other side surface in contact with the peripheral region 3. The groove 18 penetrates through the interlayer insulating film 20c, and reaches the interlayer insulating film 20b. The groove 18 has the depth D1 in the range from 1.0 μm to 1.5 μm. The groove 18 has a width of a length of about the four pixels, for example.

After the groove 18 is formed, the antireflection film 24 is formed on the interlayer insulating film 20c of the effective pixel region 2a, and on the side surfaces and bottom surface of the groove 18. As the antireflection film 24, a silicon nitride film (a Si₃N₄ film) is used, for example.

Coloring resin material containing coloring pigment and photoresist resin material is dripped on the antireflection film 24, a semiconductor wafer (a silicon wafer, for example) in which the solid state imaging device 90 is to be provided is rotated, and thereby a coating film is formed on the antireflection film 24 (a spin coat method).

After the coating film is formed, the coating film is patterned in a pixel unit by using a lithography method.

The above-described processes are sequentially performed for three primary colors of red, green, and blue colors composing the color filter 25. As a result, the color filter 25 of a red color, the color filter 25 of a green color, and the color filter 25 of a blue color are respectively formed on the antireflection film 24.

In the solid state imaging device 100 of the comparative example, the liquid pool is reduced by increasing the number of rotations of the spin coating, but the film thickness of the color filter might become thin, and thereby the color information cannot be sufficiently acquired by the photo diode 5.

On the other hand, in the solid state imaging device 90 of the embodiment, since the groove 18 is provided, the liquid pool can be reduced without increasing the number of rotations of the spin coating. That is, the film thickness of the color filter 15 does not become thin, and the liquid pool can be reduced to a large extent.

After the color filter 25 is formed, the microlenses 26 are respectively formed on the color filters 25 of each pixel unit.

As described above, according to the fabricating method according to the embodiment, it is possible to form the color filter 25 so that the film thickness is a constant thickness and becomes uniform, without changing the number of rotations of the spin coating, at the time of applying the coloring resin material of the color filter 25. The film thickness of the color filter does not become thin, and the liquid pool can be reduced.

Accordingly, it is possible to increase the effective pixel region 2a having the color filters 25 with a constant thickness.

In addition, when the effective pixel region 2a (the first region) has a rectangular shape, the depth of the groove 18 at the portions adjacent to the four corners of the effective pixel region 2a may be set to be deeper than the depth of the groove 18 at the portions adjacent to the sides of the effective pixel region 2a.

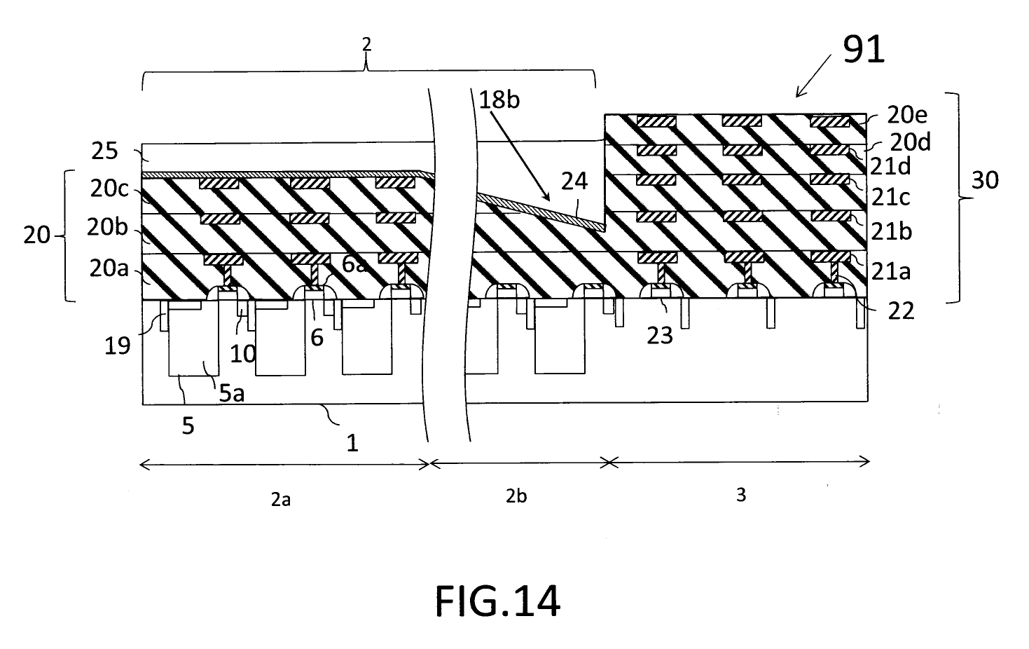

A solid state imaging device according to a second embodiment will be described with reference to the drawings. FIG. 14 is a sectional view showing a configuration of a solid state imaging device. In the embodiment, a groove is formed in the surface of the interlayer insulating film on the semiconductor substrate of the third region. The nearer to the second region side from the first region side, the deeper the groove becomes, and the groove at the portion in contact with the second region side is formed deepest. With the formation of the groove, the film thickness of the color filter on the first region is made uniform, and thereby the effective pixel region is made to be increased.

Hereinafter, the same symbols are given to the same constituent portions as the first embodiment, and the description of the portions will be omitted, and only different portions will be described.

As shown in FIG. 14, a solid state imaging device 91 is a surface irradiation type CMOS sensor in which light enters the photo diode 5 of the semiconductor substrate 1. In the solid state imaging device 91, the wiring 21 is not provided in the prohibited pixel region 2b. For this reason, the pixel 4 is not formed in the prohibited pixel region 2b.

In the solid state imaging device 91, a groove 18a is provided in the surface of the interlayer insulating film 20 (the first interlayer insulating film) of the prohibited pixel region 2b (the third region). The nearer to the peripheral region 3 (the second region) from the effective pixel region 2a (the first region) side, the deeper the groove 18a becomes. The groove 18a becomes deepest at the portion in contact with the peripheral region 3. The groove 18a is provided so as to surround the effective pixel region 2a. The groove 18a may be formed so that portions adjacent to four corners of the effective pixel region 2a are deeper than portions adjacent to sides of the effective pixel region 2a.

The antireflection film 24 is provided on the interlayer insulating film 20 (the first interlayer insulating film) of the effective pixel region 2, and on the bottom surface of the groove 18b.

The coloring resin material becomes thicker toward the peripheral region 3 side from the pixel region 2 side, and tends to form a liquid pool. In the liquid pool, the coloring resin material becomes thicker toward the peripheral region side, based on the thickness in the vicinity of the center of the pixel region 2.

In the solid state imaging device 91 of the embodiment, the groove 30 is provided whose depth becomes maximum at the portion in contact with the peripheral region 3. As a result, it is possible to make the thickness of the color filters 25 more uniform. Since it is possible to increase the region where the height of the color filter 25 is uniform, the range where the light which has passed through the color filter 25 can be acquired by the photo diode 5 without color information unevenness is enlarged.

While certain embodiments have been described, these embodiments have been presented by way of example only, and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid state imaging device, comprising:
a semiconductor substrate including a first region in which a photoelectric conversion device is provided, a second region which is provided around the first region and in which a device is provided, and a third region which is provided between the first region and the second region and in which the photoelectric conversion device is provided;
a first interlayer insulating film provided on the first region and the third region;
a second interlayer insulating film provided on the second region with a thickness larger than the first interlayer insulating film; and
a resin material which is provided on the first interlayer insulating film of the first region, and provided on a groove in a surface of the first interlayer insulating film of the third region.

2. The device according to claim 1, wherein the groove becomes deeper toward the second region side from the first region side.

3. The device according to claim 1, wherein the groove is deepest at the second region side.

4. The device according to claim 1, wherein the groove is provided so as to surround the first region.

5. The device according to claim 2, wherein:
the first region has a rectangular shape from a surface side,
each of the second region and the third region has a frame shape from a surface side; and
the groove is formed so that portions adjacent to four corners of the first region are deeper than portions adjacent to sides of the first region.

6. The device according to claim 1, wherein:
a wiring is provided in the first interlayer insulating film of the first region and the second interlayer insulating film; and
a wiring is not provided in the first interlayer insulating film of the third region.

7. The device according to claim 1, wherein the first interlayer insulating film and the second interlayer insulating film are silicon dioxide film

8. The device according to claim 1, wherein the resin material is a color filter.

9. The device according to claim 1, wherein an antireflection film is provided between the resin material and the first interlayer insulating film of the first region, and between the resin material and both a bottom surface and side surfaces of the groove.

10. The device according to claim 1, wherein a microlens is provided on the resin material of the first region.

11. The device according to claim 1, wherein transfer transistors are respectively provided at a boundary region between the first region and the first interlayer insulating film, and at a boundary region between the third region and the first interlayer insulating film.

12. The device according to claim 1, wherein an element isolation layer is provided at an upper side surface of the photoelectric conversion device.

13. The device according to claim 1, wherein the solid state imaging device is a surface irradiation type CMOS sensor.

14. A method of fabricating a solid state imaging device, comprising:
forming a photoelectric conversion device at a surface of a semiconductor substrate;
forming a device at a surface around a photoelectric conversion device forming region of the semiconductor substrate;
forming a first interlayer insulating film on the photoelectric conversion device forming region;
forming a second interlayer insulating film with a thickness larger than the first interlayer insulating film, on a device forming region of the semiconductor substrate;
forming a groove in a surface of a region of the first interlayer insulating film in contact with the second interlayer insulating film; and
forming a resin material on the first interlayer insulating film of the first region and the second region.

15. The method according to claim 14, wherein the resin material is formed with a constant height.

16. The method according to claim 14, wherein the groove is formed using an RIE method.

17. The method according to claim 14, wherein the semiconductor substrate is a silicon substrate.

18. The method according to claim 14, further comprising:
applying the resin material on the first interlayer insulating film, rotating the semiconductor substrate.

19. The method according to claim 14, further comprising:
forming an antireflection film. between the resion material and the first interlayer insulating film of the first region, and between the resion material and both a bottom surface and side surface of the groove.

20. The method according to claim 14, further comprising:
forming a microlens over the first interlayer insulating film, after forming the resin material.
